(19) United States
(12) Patent Application Publication
(10) Pub. No.: US 2012/0269003 A1
(43) Pub. Date: Oct. 25, 2012

(54) DATA DECISION METHOD AND MEMORY

(76) Inventors: Sang-Sik KIM, Gyeonggi-do (KR); Jun-Rye RHO, Gyeonggi-do (KR); Sang-Chul LEE, Gyeonggi-do (KR)

(21) Appl. No.: 13/454,439

(22) Filed: Apr. 24, 2012

(30) Foreign Application Priority Data
Apr. 25, 2011 (KR) 10-2011-0038476

(51) Int. Cl. G11C 16/06

(52) U.S. Cl. 365/185.22

(57) ABSTRACT

A data decision method including checking whether threshold voltages of a plurality of memory cells are greater than a first verification voltage, checking whether the threshold voltages of the plurality of memory cells are greater than a second verification voltage, wherein the second verification voltage is greater than the first verification voltage, and checking threshold voltages of memory cells adjacent to memory cells having threshold voltages greater than the first verification voltage and lower than the second verification voltage among the plurality of memory cells.

### CROSS-REFERENCE TO RELATED APPLICATIONS

The present application claims priority of Korean Patent Application No. 10-2011-0038476, filed on Apr. 25, 2011, which is incorporated herein by reference in its entirety.

### BACKGROUND

1. Field

Exemplary embodiments of the present invention relate to a data decision method and a memory.

2. Description of the Related Art

When a program operation is operated in a memory cell of a non-volatile memory, electrons are stored in a conductive band of a floating gate using Fouler-Nordheim (F-N) tunneling. According to this operation, a threshold voltage is increased by charges stored in the conductive band of the floating gate. According to this operation, characteristics of each memory cell within the non-volatile memory device are different, and therefore, the memory cell has a designated threshold voltage distribution.

The non-volatile memory includes a memory cell array that stores data. The memory cell array is configured to include a plurality of memory blocks. Each memory block includes a plurality of pages. Each page is configured to include a plurality of memory cells. Each memory cell has different threshold voltage distributions according to data stored in the memory cells. The non-volatile memory performs an erase operation in a memory block unit and performs writing or reading operation in a page unit.

The threshold voltage of the memory cell in the non-volatile memory has different voltage distributions according to the stored data values. The data values stored in the memory cells may be read by the above described properties at the time of the reading operation. For example, a single level cell (hereinafter, referred to as “an SLC”) capable of storing 1-bit of data has an erase state (storing an erase data) or a program state (storing program data). The threshold voltage distributions of the memory state in the erase state are lower in average than the threshold voltage distributions of the memory cells in the program state. At the time of reading data, the data of the memory cell having a greater threshold voltage than a verification voltage having a level between both voltage distributions are read as program data, and the data of the memory cell having a lower threshold voltage than the verification voltage is read as an erase data.

Therefore, to accurately read the data stored in the memory cell, the threshold voltage distributions of the memory cell where different data is stored do not overlap. However, the threshold voltage distributions of the memory cell where another data are stored occur due to several factors. These factors may be as follows.

First, as an example, a margin may be insufficient in a multi level cell (hereinafter, referred to as “an MLC”) storing multi-bit data. Since the stored data values are various, the MLC has more threshold voltage distributions than the SLC. For example, the multi bit cell for storing two-bit data has four threshold voltage distributions. Therefore, the voltage range permitted as the threshold voltage range is more subdivided than the SLC and is used as the threshold voltage distributions of the memory cell. Therefore, a distance between the adjacent threshold voltage distributions approximates to each other and thus, the voltage distributions are likely to overlap.

Next, there is another example that the adjacent memory cells have been affected. In the ideal case, the threshold voltage of the memory cell needs to be determined according to the data value stored in the memory cell. However, a variety of parasitic capacitances are present in the non-volatile memory. The threshold voltage of the memory cell may be affected by a program pulse applied to the adjacent memory cells due to the parasitic capacitances. When the threshold voltage of the memory cell shifts due to the effect of the adjacent memory cell, the threshold voltages of the memory cells where data is stored may overlap with other.

Finally, since the device characteristics are not ideal, the threshold voltage of the memory cell changes over time. If the device characteristics are ideal, the threshold voltage of the memory cell is permanently maintained as the threshold voltage at the time of the program. However, the threshold voltage of the memory cell changes over time. Therefore, at a time when the memory cell is programmed, the threshold voltage distributions of the memory cell maintain a narrow distribution and thus, do not overlap with each other, but the threshold voltage distributions are expanded and thus, overlap the adjacent threshold voltage distributions in some periods.

When the threshold voltage distributions overlap with each other, reading the data of the memory cell may be difficult in the period when the threshold voltages overlap with each other.

### SUMMARY

An embodiment of the present invention is directed to a data decision method and a non-volatile memory for accurately reading data of a memory cell when threshold voltage distributions of a memory cell where different data is stored overlap with each other.

In accordance with an embodiment of the present invention, a data decision method includes: checking whether threshold voltages of a plurality of memory cells are greater than a first verification voltage; checking whether the threshold voltages of the plurality of memory cells are greater than a second verification voltage, wherein the second verification voltage is greater than the first verification voltage; and checking threshold voltages of memory cells adjacent to memory cells having threshold voltages greater than the first verification voltage and lower than the second verification voltage among the plurality of memory cells.

In accordance with another embodiment of the present invention, a memory includes: a plurality of first memory cells; a plurality of second memory cells adjacent to the plurality of first memory cells; and a plurality of page buffers configured to read data of the first memory cells having threshold voltages that are lower than a first verification voltage as first data, read data of the first memory cells having threshold voltages that are greater than a second verification voltage as second data, and read data of the first memory cells having threshold voltages that is greater than the first verification voltage and lower than the second verification voltage in response to data stored in the plurality of second memory cells, wherein the second verification voltage is greater than the first verification voltage.

### BRIEF DESCRIPTION OF THE DRAWINGS

FIG. 1 is a diagram illustrating threshold voltage distributions of memory cells (meaning SLC in FIG. 1) that are in an erase state.

FIG. 2 is a diagram illustrating the threshold voltage distributions of the memory cells (meaning SLC in FIG. 2) where different data are stored overlap with each other.

FIG. 3 is a diagram illustrating a principle of a data decision method in accordance with an embodiment of the present invention.

FIG. 4 is a flow chart illustrating the data decision method in accordance with the embodiment of the present invention shown in FIG. 3.

FIG. 5 is a configuration diagram of a non-volatile memory in accordance with an embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

Hereinafter, exemplary embodiments of the present invention will be described with reference to the accompanying drawings so that a person with an ordinary skilled in the art to which the present invention pertains can easily carry out technical ideas of the present invention.

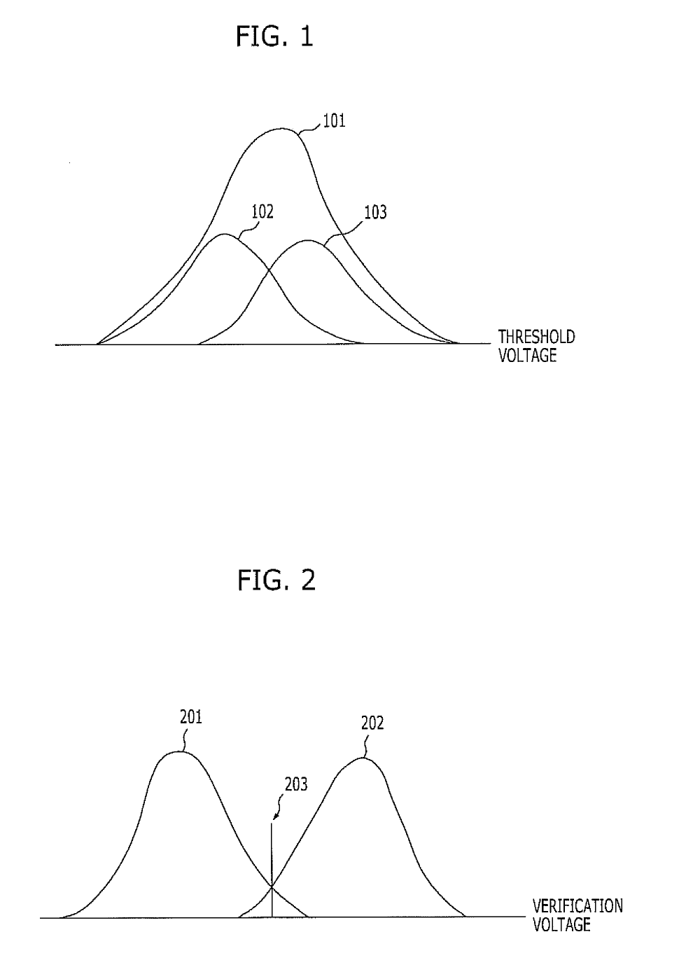

FIG. 1 is a diagram illustrating threshold voltage distributions of memory cells that are in an erase state. In FIG. 1, the memory cells are SLCs.

As illustrated in FIG. 1, the threshold voltage distributions of the memory cells that are in the erase state shows a normal distribution (101). In this example, the memory cells having the threshold voltages included in the voltage distributions of FIG. 1 may be classified as memory cells that have adjacent memory cells in the erase state and memory cells that have adjacent memory cells in the program state. According to this example, the memory cells adjacent to the specific memory cells mean the memory cells connected below the specific memory cells, among the memory cells included in the same cell string. For example, when cell A and cell B are included in the same cell string and the cell B is connected below the cell A, the cell B is the memory cell adjacent to the cell A.

In FIG. 1, reference numeral ‘102’ among the voltage distributions shown below reference numeral ‘101’ shows the threshold voltage distributions of the memory cells that have adjacent memory cells in the erase state among the memory cells in the erase state. Reference numeral ‘103’ shows the threshold voltage distributions of the memory cells that have adjacent memory cells in the program state among the memory cells in the erase state.

The state of the memory cell corresponding to the SLC has, for example, only two states such as the erase state or and the program state. Therefore, the sum of the number of memory cells that have adjacent memory cells in the erase state among the memory cells in the erase state and the number of memory cells that have adjacent memory cells in the program state among the memory cells in the erase state is the same as the number of memory cells that are the erase state. More specifically, the sum of reference numerals ‘102’ and ‘103’ is ‘101’. In addition, reference numerals ‘102’ and ‘103’ are different in average and correspond to the same normal distribution curve.

The reason why the average of reference numeral ‘102’ is greater than that of reference numeral ‘103’ is that the adjacent memory cells are in the program state. In this example, the memory cells that have adjacent memory cells are in the program state among the memory cells have a large inter-cell interference (ICI) weight, and the memory cells that have adjacent memory cells in the erase state among the memory cells have a small ICI weight.

When the threshold voltages of the memory cells that are the erase state are not affected by the adjacent memory cells, the average of reference numerals ‘102’ and ‘103’ is the same. Therefore, the number of memory cells that have adjacent cells in the erase state among the memory cells having the specific threshold voltage should be the same as the number of memory cells that have adjacent cells in the program state. More specifically, the ratio of the number of memory cells having the specific threshold voltage to the number of memory cells that have adjacent memory cells in the erase state (or the program state) among the memory cells having the specific threshold voltages may be equally set to ½ in the entire period of the voltage distributions.

However, the ratio of the number of memory cells having the specific threshold voltages to the number of memory cells that have adjacent memory cells in the erase state (or the program state) among the memory cells having the specific threshold voltages is changed according to the level of the specific threshold voltage due to the difference in the ICI weight. The ratio of the memory cell having the large ICI weight is relatively high in the right region of the voltage distribution 101, and the ratio of the memory cell having the small ICI weight is high in the left region of the voltage distribution 101. More specifically, in FIG. 1, more memory cells that have adjacent memory cells in the program state are present in the right region of the voltage distribution 101, and more memory cells that have adjacent memory cells in the erase state are present in the left area of the voltage distribution 101.

FIG. 2 is a diagram illustrating the threshold voltage distributions of the memory cells (meaning SLC in FIG. 2) where different data are stored overlap with each other. In FIG. 2, the memory cells are SLCs.

As illustrated in FIG. 2, when a voltage distribution 201 (hereinafter, referred to as “a first distribution 201”) of the memory cells that are the erase state, and a voltage distribution 202 (hereinafter, referred to as “a second distribution 202”) of the threshold voltages of the memory cells that are the program state overlap with each other, errors may occur at the time of the read operation.

For example, the data of the memory cells are assumed to be read using a verification voltage 203. In the memory cell that has the threshold voltages lower than the verification voltage 203, the erase data is read, and in the memory cell that has threshold voltages greater than the verification voltage 203, the program data is read. When the first distribution 201 and the second distribution 203 do not overlap with each other, the operation does not cause any errors.

However, as illustrated in FIG. 2, when the first distribution 201 and the second distribution 202 overlap with each other, some memory cells have threshold voltages greater than the verification voltage 203 among the memory cells where the erase data is stored, i.e., the memory cells in the erase state. Further, some memory cells have threshold voltages lower than the verification voltage 203 among the memory cells where the program data is stored, i.e., the memory cells in the program state. As described above, when the data is read according to whether the threshold voltage is lower or greater based on the verification voltage 203, data different from the stored data may be read.

As described above, to increase the possibility that the correct data is read in the period when the first distribution 201 and the second distribution 203 overlap with each other, the data of the selected memory cell may be read using the data stored in the adjacent memory cells rather than the selected memory cells.

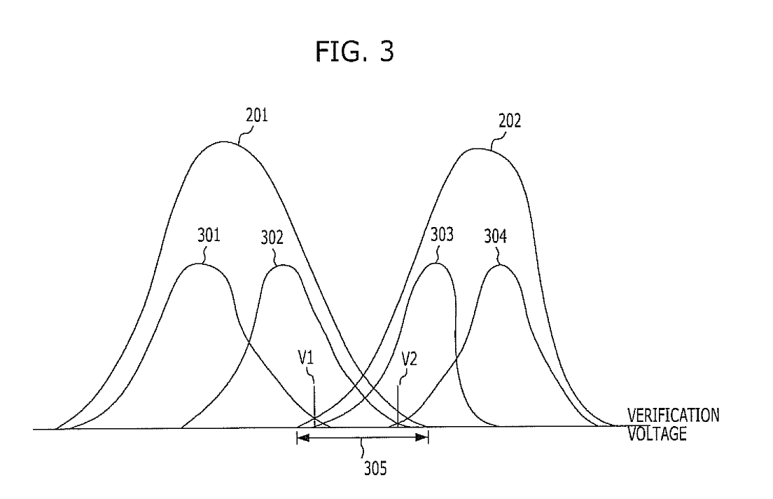

FIG. 3 is a diagram illustrating a principle of the data decision method in accordance with an embodiment of the present invention.

FIG. 3 separately illustrates threshold voltage distributions according to whether adjacent memory cells are in an erase state or a program state in the first distribution 210 and the second distribution 202 of FIG. 2. A 1-1 distribution 301 is a threshold voltage distribution of memory cells that have adjacent memory cells in the erase state among the memory cells in the erase state, and a 1-2 distribution 302 is a threshold voltage distribution of memory cells that have adjacent memory cells in the program state among the memory cells in the erase state. A 2-1 distribution 303 is a threshold voltage distribution of memory cells that have adjacent memory cells in the erase state among the memory cells in the program state, and a 2-2 distribution 304 is a threshold voltage distribution of memory cells that have adjacent memory cells in the program state among the memory cells in the erase state. A relation between the first distribution 201 and sub-distributions 301 and 302 of the first distribution and a relation between a second distribution 202 and sub-distributions 303 and 304 are the same of a relation between 101 and 102 and 103 described in FIG. 1.

In FIG. 3, describing a period 305 (hereinafter, referred to as “an overlapping period 305”) where the first distribution 201 and the second distribution 203 overlap with each other, the overlapping period 305 is positioned in the right region of the first distribution 201 and the left region of the second distribution 203.

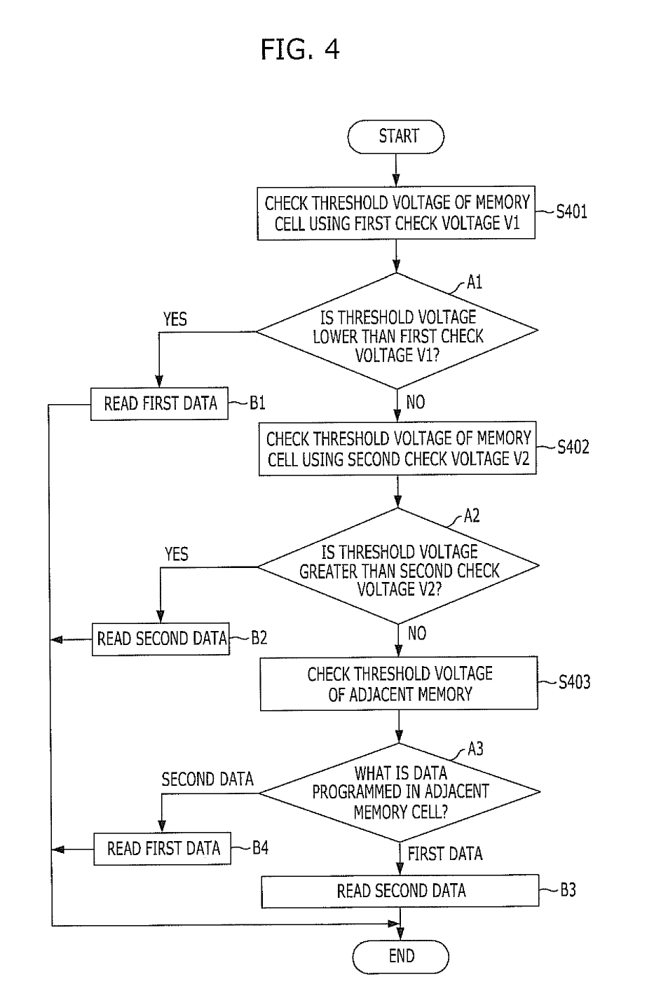

When the relation between the first distribution 201 and the sub-distribution 301 and 302 of the first distribution is considered, most of the memory cells in the erase state among the memory cells that include the threshold voltages in the overlapping period 305 are the memory cells that have adjacent memory cells in the program state and have the large ICI weight. In addition, when the relation between the second distribution 202 and the sub-distribution 303 and 304 of the second distribution is considered, most of the memory cells in the program state among the memory cells that include the threshold voltages in the overlapping period 305 are the memory cells that have adjacent memory cells in the erase state and have the small ICI weight. The probability that the wrong data is read may be reduced at the time of the read operation by determining the data read from the memory cell in the overlapping period 305 by a method described below in the description of FIG. 4 using the above-mentioned properties.

FIG. 4 is a flow chart illustrating the data decision method in accordance with the embodiment of the present invention shown in FIG. 3.

As illustrated in FIG. 4, the data decision method includes checking whether the threshold voltages of the plurality of memory cells are greater or lower than a first verification voltage V1 (S401), checking whether the threshold voltage of the plurality of memory cells is greater or lower than a second verification voltage V2, which is greater than the first verification voltage V1 (S402), and checking the threshold voltage of the memory cells adjacent to the memory cells of the threshold voltages that are greater than the first verification voltage V1 and lower than the second verification voltage V2 among the plurality of memory cells (S403).

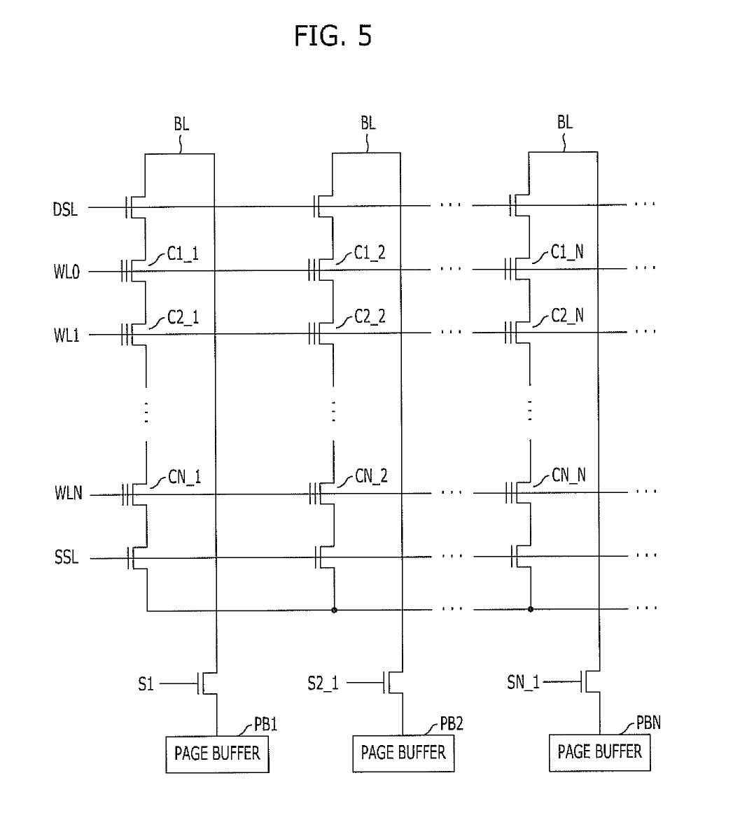

Hereinafter, the adjacent memory cells means the memory cells connected below the selected memory cells while being included in the same cell string as the memory cell selected by the activated word lines. The description relating to the cell string will be described in the description of FIG. 5. A period between the first verification voltage V1 and the second verification voltage V2 illustrated in FIG. 3 is referred to as “a verification period”. In addition, the bit number of data when the wrong value is read among the data read from the plurality of memory cells is referred to as “an error bit number”. Here, the data when the wrong value is read is determined by comparing the original data stored in the plurality of memory cells with the data read from the plurality of memory.

The data decision method will be described with reference to FIG. 4.

When the reading operation starts by receiving a read command, whether the threshold voltages of the plurality of memory cells are greater or lower than the first verification voltage V1 (S401) (hereinafter, referred to as “a first verification (S401)”) is confirmed. As a result of performing the first verification (S401), the data of the memory cells having threshold voltages lower than the first verification voltage V1 among the plurality of memory cells are determined and read as the first data (proceed to a path of ‘YES’ at A1 and B1). The data of the memory cells having the threshold voltages greater than the first verification voltage V1 among the plurality of memory cells are not determined by the first verification (S401) (proceed to a path of ‘NO’ at A1).

The data of the memory cells having the threshold voltages greater than the first verification voltage V1 among the plurality of memory cells are not determined, and the method proceeds to the next process along the path of ‘NO’ at A1. Next, whether the threshold voltages of the plurality of memory cells are greater or lower than the second verification voltage V2 (S402) (hereinafter, referred to as “a second verification (S402)”) is checked. As the result of performing the second verification (S402), the data of the memory cells having the threshold voltages greater than the second verification voltage V2 among the plurality of memory cells are determined and read as the second data (proceed to a path of ‘YES’ at A2 and B2). The data of the memory cells having the threshold voltages greater than the first verification voltage V1 and lower than the second verification voltage V2 among the plurality of memory cells are not determined by the second verification (S402) (proceed to a path of ‘NO’ at A2).

In this embodiment, the first verification (S401) and the second verification (S402) are not necessarily performed in the order described above, and the second verification (S402) may be performed before the first verification (S401).

The data stored in the memory cells having the threshold voltages greater that the first verification voltage V1 and lower than the second verification voltage V2 among the plurality of memory cells, i.e., the memory cells of the threshold voltage are included in the verification period, are determined by the data stored in the adjacent memory cells. More specifically, the threshold voltages of the memory cells adjacent to the plurality of memory cells are checked (S403) (hereinafter, referred to as “a third verification (S403)”).

Hereinafter, the first data corresponds to the erase data and the second data corresponds to the program data. Therefore, the threshold voltage distributions of the memory cells where the first data are stored have the first distribution 201 and the threshold voltage distributions of the memory cells where the second data are stored have the second distribution 202.

As described above in the description of FIGS. 1 to 3, since the ICI weight becomes larger as the threshold voltage of the adjacent memory is greater, the ICI weight is small when the first data are stored in the adjacent memory cell, and the ICI weight is large when the second data are stored in the adjacent memory cell. The memory cells having the large ICI weight among the memory cells included in the overlapping period 305 are highly likely to be the memory cells included in the right region of the first distribution 201, and the memory cells having the small ICI weight are highly likely to be the memory cells included in the left region of the second distribution 202.

Therefore, if the data of the selected memory cells having the threshold voltages greater than the first verification voltage V1 and lower than the second verification voltage V2 has an adjacent memory cell with first data stored in the adjacent memory cell, the selected memory cells are determined and read as the second data (proceed to a path of ‘first data’ at A3 and B3). In addition, if the data of the selected memory cells having the threshold voltages greater than the first verification voltage V1 and lower than the second verification voltage V2 has an adjacent memory cell with second data stored in the adjacent memory cell, the selected memory cells are determined and read as the first data (proceed to a path of ‘second data’ at A3 and B4).

Meanwhile, the data decision method in accordance with the embodiment of the present invention further includes setting a voltage level of the first verification voltage V1, and a voltage level of the second verification voltage V2 greater than the first verification voltage V1 before the first verification (S401) (not shown in FIG. 4) (hereinafter, referred to as “a voltage level setting”). In the voltage level setting, the voltage levels of the first and second verification voltages V1 and V2 are set at the same time when an operational environment of a memory device is set as the memory device is powered on. The voltage levels of the first and second verification voltages V1 and V2 are a designated value inside a system including the memory device or an inputted value from a circuit outside the system including the memory device.

The data decision method in accordance with the embodiment of the present invention checks the threshold voltages (corresponding to the data stored in the adjacent memory cells) of the adjacent memory cells using the fact in that the ICI weights of the memory cells that are in the erase state included in the overlapping period 305 and the memory cells that are the program state are different from each other. The data decision method can thereby determine and read the data of the selected memory cells. Using the data decision method can reduce the error bit number of the data read from the plurality of memory cells.

Meanwhile, width of the verification period between the first verification voltage V1 and the second verification voltage V2 may be set by the user. The verification period may be a part or all of the overlapping period 305. The error bit number is determined according to the verification period and thus, the first verification voltage V1 and the second verification voltage V2 are set so that the error bit number of the data read from the plurality of memory cells is minimized. However, since characteristics are specific to each memory, the width of the verification period may be changed for each memory. Therefore, the first verification voltage V1 and the second verification voltage V2 are set as the following method.

The first verification voltage V1 may be set so that a ratio of the number of memory cells having the threshold voltages that are the first verification voltage V1 to the number of memory cells where the data of the adjacent memory cells among the memory cells having the threshold voltages that are the first verification voltage V1 are the first data so that the error bit number of the data read from the plurality of memory cells is minimal. The second verification voltage V2 may be set so that a ratio of the number of memory cells having the threshold voltages that are the second verification voltage V2 to the number of memory cells where the data of the adjacent memory cells among the memory cells having the threshold voltages that are the second verification voltage V2 are the first data so that the error bit number of the data read from the plurality of memory cells is minimal.

Alternatively, the first verification voltage V1 may be set so that a ratio of the number of memory cells having the threshold voltages that are the first verification voltage V1 to the number of memory cells where the data of the adjacent memory cells among the memory cells having the threshold voltages that are the first verification voltage V1 are the second data so that the error bit number of the data read from the plurality of memory cells is minimal/reduced. The second verification voltage V2 may be set so that a ratio of the number of memory cells having the threshold voltages that are the second verification voltage V2 to the number of memory cells where the data of the adjacent memory cells among the memory cells having the threshold voltages that are the second verification voltage V2 are the second data so that the error bit number of the data read from the plurality of memory cells is minimal/reduced.

More specifically, during the test, the first and second verification voltages V1 and V2 are determined by a ratio of the number of memory cells having the threshold voltages that minimize/reduce the error bit number to the number of memory cells where the data of the adjacent memory cells is the specific data (first data or second data) among the memory cells having the threshold voltages that are the first and second verification voltages V1 and V2.

For example, through the test, the number of memory cells where the threshold voltage is the first verification voltage V1 are 100, the number of memory cells where the data of the adjacent memory cells are the first data among the memory cells having the threshold voltages that are the first verification voltage V1 is 20 (the ratio of 5:1), the number of memory cells having the threshold voltages that are the second verification voltage V2 is 100, and the number of memory cells where the data of the adjacent memory cells are the first data are 80 (the ratio of 5:4) among the memory cells having the threshold voltages that are the second verification voltage V2, and the error bit number of the data read from the plurality of memory cells are minimized/reduced. In this example, the first verification voltage V1 may be 1.6 V and the second verification voltage may be 1.8 V.

In this example, 1.6V and 1.8V are not a reference of setting the verification period, but the ratio (5:1 and 5:4) of the number of memory cells is a reference of setting the verification period. When determining the verification period using the ratio of the number of memory cells, the verification period may be set so that the error bit number of the data read from the plurality of memory cells is minimized/reduced even though the memory is changed.

FIG. 5 is a configuration diagram of a memory in accordance with an embodiment of the present invention.

The memory of FIG. 5 is a memory reading the data of a plurality of first memory cells C1_1 to C1_N using the above-mentioned data decision method in the description of FIG. 4.

As illustrated in FIG. 5, the memory includes a plurality of first memory cells C1_1 to C1_N, a plurality of second memory cells C2_1 to C2_N adjacent to the plurality of first memory cells C1_1 to C1_N, and a plurality of page buffers PB1 to PBN that reads the data of the first memory cells C1_1 to C1_N having the threshold voltages that are lower than the first verification voltage V1 among the plurality of first memory cells C1_1 to C1_N as the first data, the data of the first memory cells C1_1 to C1_N having the threshold voltages that are greater than the second verification voltage V2 greater than the first verification voltage V1 among the plurality of first memory cells C1_1 to C1_N as the second data, and the data of the first memory cells C1_1 to C1_N having the threshold voltages that are greater than the first verification voltage V1 and lower than the second verification voltage V2 as the data determined according to the data stored in the plurality of second memory cells C2_1 to C2_N.

The plurality of first memory cells C1_1 to C1_N and the plurality of second memory cells C2_1 to C2_N each are included in the cell string. The cell string means a string structure that is connected between the source selection transistor (transistor receiving SSL) and the drain selection transistor (transistor receiving DSL) in series. The source selection transistor is connected to a bit line (BL). The floating gate of each cell (memory cell and flag cell) included in the cell string is applied with various voltage by a plurality of word lines WL0, WL1, and WLN.

Hereinafter, an example where the plurality of first memory cells C1_1 to C1_N represents a plurality of memory cells connected to WL0 and the plurality of second memory cells C2_1 to C2_N represents the plurality of memory cells connected to WL1 will be described. Transistors receiving ‘S1 to SN’ correspond to transistors to electrically connect or block the bit line BL with the plurality of page buffers PB1 to PBN according to the memory operation. In particular, the memory cells corresponding to each other among the plurality of first memory cells C1_1 to C1_N and the plurality of second memory cells C2_1 to C2_N each are included in the same cell string.

Hereinafter, the memory operation will be described with reference to FIG. 5.

When the operation for reading the data by the read command for reading of the data of the plurality of first memory cells C1_1 to C1_N starts, the data of the first memory cells having the threshold voltages that are lower than the first verification voltage V1 among the plurality of first memory cells C1_1 to C1_N among the plurality of page buffers PB1 to PBN is determined to be the first data. Next, the data of the first memory cells having the threshold voltages that are greater than the second verification voltage V2 is determined to be the second data among the plurality of first memory cells C1_1 to C1_N. As described above in FIG. 4, the first data corresponds to the erase data and the second data corresponds to the program data.

Further, the plurality of page buffer PB1 to PBN check the data stored in the plurality of second memory cells C2_1 to C2_N so as to determine the data of the first memory cells where the threshold voltage is greater than the first verification voltage V1 and lower than the second verification voltage V2 among the plurality of first memory cells C1_1 to C1_N. Subsequently, the data of the first memory cell where the threshold voltage is included in the verification period is determined according to the data stored in the second memory cell adjacent to the first memory cell. Finally, the data of the plurality of determined first memory cells C1_1 to C1_N are read.

The method of determining the data of the first memory cell having the threshold voltages that are included in the verification period is as follows. The data stored in the first memory cell where the data stored in the second memory cell corresponding to the first memory cell is the first data are determined and read as the second data and the data stored in the first memory cell where the data stored in the second memory cell corresponding to the first memory cell is the second data are determined and read as the first data. The reason is the ICI weight and is the same as one described in FIG. 4.

Meanwhile, width of the verification period between the first verification voltage V1 and the second verification voltage V2 may be set by the user. The verification period may be a part or all of the overlapping period 305. The error bit number is determined according to the verification period and thus, the first verification voltage V1 and the second verification voltage V2 are set so that the error bit number of the data read from the plurality of memory cells is minimal. However, since characteristics are for each memory, the width of the verification period for minimizing the error bit number of the read data may be changed for each memory. Therefore, the first verification voltage V1 and the second verification voltage V2 are set as the following method.

The first verification voltage V1 may be set so that the ratio of the number of first memory cells having the threshold voltages that are the first verification voltage V1 to the number of first memory cells where the data of the adjacent second memory cells among the first memory cells having the threshold voltages that are the first verification voltage V1 are the first data so that the error bit number of the data read from the plurality of first memory cells C1_1 to C1_N is minimal. The second verification voltage V2 may be set so that the ratio of the number of first memory cells having the threshold voltages that are the second verification voltage V2 to the number of first memory cells where the data of the adjacent second memory cells among the first memory cells having the threshold voltages that are the second verification voltage V2 are the first data so that the error bit number of the data read from the plurality of memory cells C1_1 to C1_N is minimal.

Alternatively, the first verification voltage V1 may be set so that the ratio of the number of first memory cells having the threshold voltages that are the first verification voltage V1 to the number of first memory cells where the data of the adjacent second memory cells among the first memory cells having the threshold voltages that are the first verification voltage V1 are the second data so that the error bit number of the data read from the plurality of first memory cells C1_1 to C1_N is minimal. The second verification voltage V2 may be set so that the ratio of the number of first memory cells having the threshold voltages that are the second verification voltage V2 to the number of first memory cells where the data of the adjacent second memory cells among the first memory cells having the threshold voltages that are the second verification voltage V2 are the second data so that the error bit number of the data read from the plurality of first memory cells C1_1 to C1_N is minimal.

The memory effect of FIG. 5 is the same as the effect of the data decision method of FIG. 4. In addition, although FIG. 5 describes an example of an NAND flash memory that is a non-volatile memory, this is for illustration purposes. Therefore, the memory in accordance with the embodiment of the present invention is not limited to the NAND flash memory but may be applied to a memory cell that is affected by the state of the adjacent memory cell or the data stored in the adjacent memory cells.

Although in the above description the memory cell is the SLC, the data decision method and the memory according to the embodiment of the present invention may also be applied to a memory cell that is the MLC. For example, the memory may include the plurality of memory cells (corresponding to the MLC) capable of storing 2-bit data. The plurality of memory cells may be stored with ‘11’, ‘01’, ‘10’, ‘00’. The effect on the threshold voltages of the adjacent memory cells may be changed according to the data values stored in the memory cells. More specifically, the ICI weight is changed. Therefore, the embodiment of the present invention may be applied. For example, when the threshold voltage distributions of the memory cells where ‘11’ is stored overlap with the threshold voltage distributions of the memory where ‘01’ is stored, the verification period is set and the data of the memory cells where the threshold voltages are included in the verification period may be determined using the data stored in the adjacent memory cells. As the result of checking the data stored in the adjacent memory cells in the verification period, the data of the memory cell having the large ICI weight are determined and read as ‘11,’ and as the result of checking the data stored in the adjacent memory cells, the data of the small memory cells having the small ICI weight are determined and read as ‘01’.

As set forth above, the data decision method and the non-volatile memory in accordance with the embodiments of the present invention can accurately read the data of the memory cell included in the period when the threshold voltage distributions of the memory cell where different data is stored overlap with each other by using the threshold voltages of the memory cells adjacent to the corresponding memory cell.

While the present invention has been described with respect to the specific embodiments, it will be apparent to those skilled in the art that various changes and modifications may be made without departing from the spirit and scope of the invention as defined in the following claims.

What is claimed is:

1. A data decision method comprising:
checking whether threshold voltages of a plurality of memory cells are greater than a first verification voltage;
checking whether the threshold voltages of the plurality of memory cells are greater than a second verification voltage, wherein the second verification voltage is greater than the first verification voltage; and
checking threshold voltages of memory cells adjacent to memory cells having threshold voltages greater than the first verification voltage and lower than the second verification voltage among the plurality of memory cells.

2. The data decision method of claim 1, wherein data stored in the memory cells having the threshold voltages greater than the first verification voltage and lower than the second verification voltage among the plurality of memory cells are determined to be data including first data and second data according to data stored in memory cells adjacent thereto.

3. The data decision method of claim 1, wherein data stored in the memory cells having the threshold voltages lower than the first verification voltage among the plurality of memory cells are determined to be first data, and data stored in the memory cells having the threshold voltages greater than the second verification voltage among the plurality of memory cells are determined to be second data.

4. The data decision method of claim 3, wherein the threshold voltages of the memory cells storing the first data has voltage distribution lower than the threshold voltages of the memory cells storing the second data.

5. The data decision method of claim 3, wherein the data stored in selected memory cells having the threshold voltages greater than the first verification voltage and lower than the second verification voltage among the plurality of memory cells are determined to be the second data when data stored in memory cells adjacent to the selected memory cells is the first data and is determined to be the first data when the data stored in the memory cells adjacent the selected memory cells is the second data.

6. The data decision method of claim 5, wherein the memory cells in which the second data are stored among the adjacent memory cells change the threshold voltages of the memory cells adjacent thereto more than the memory cells in which the first data are stored among the adjacent memory cells.

7. The data decision method of claim 1, wherein the first and second verification voltages are set so that a number of error bits of data read from the plurality of memory cells is reduced.

8. The data decision method of claim 7, wherein the first verification voltage is set so that a ratio of the number of memory cells having threshold voltages that are the first verification voltage to the number of memory cells having adjacent memory cells that contain the first data among the memory cells having the threshold voltages that are the first verification voltage so that the number of error bits of the data read from the plurality of memory cells is reduced, and the second verification voltage is set so that a ratio of the number of memory cells having threshold voltages that are the second verification voltage to the number of memory cells having adjacent memory cells that contain the first data among the memory cells having the threshold voltages that are the second verification voltage so that the number of error bits of the data read from the plurality of memory cells is reduced.

9. The data decision method of claim 7, wherein the first verification voltage is set so that a ratio of the number of memory cells having threshold voltages that are the first verification voltage to the number of memory cells having adjacent memory cells that contain the second data among the memory cells having the threshold voltages that are the first verification voltage so that the number of error bits of the data read from the plurality of memory cells is reduced, and the second verification voltage is set so that a ratio of the number of memory cells having threshold voltages that are the second verification voltage to the number of memory cells having adjacent memory cells that contain the second data among the memory cells having the threshold voltages that are the second verification voltage so that the number of error bits of the data read from the plurality of memory cells is reduced.

10. The data decision method of claim 2, wherein the first data is data in an erase state, and the second data is data in a programmed state.

11. A memory comprising:
a plurality of first memory cells;
a plurality of second memory cells adjacent to the plurality of first memory cells; and
a plurality of page buffers configured to read data of the first memory cells having threshold voltages that are lower than a first verification voltage as first data, read data of the first memory cells having threshold voltages that are greater than a second verification voltage as second data, and read data of the first memory cells having threshold voltages that is greater than the first verification voltage and lower than the second verification voltage in response to data stored in the plurality of second memory cells,
wherein the second verification voltage is greater than the first verification voltage.

12. The memory of claim 11, wherein the data stored in selected first memory cells having the threshold voltages that are greater than the first verification voltage and lower than the second verification voltage among the plurality of first memory cells is determined to be the second data when data stored in second memory cells corresponding to the selected first memory cells among the plurality of second memory cells is the first data, and is determined to be the first data when the data stored in the second memory cells corresponding to the selected first memory cells among the plurality of second memory cells is the second data.

13. The memory of claim 11, wherein the threshold voltages of the memory cells storing the first data has voltage distribution lower than that of the threshold voltages of the memory cells storing the second data.

14. The memory of claim 11, wherein the first and second verification voltages are set so that a number of error bits of data read from the plurality of memory cells is reduced.

15. The memory of claim 14, wherein the first verification voltage is set so that a ratio of the number of first memory cells having threshold voltages that are the first verification voltage to the number of first memory cells having adjacent second memory cells that contain the first data among the first memory cells having the threshold voltages that are the first verification voltage so that the number of error bits of the data read from the plurality of first memory cells is reduced, and the second verification voltage is set so that a ratio of the number of first memory cells having threshold voltages that are the second verification voltage to the number of memory cells having the adjacent second memory cells that contains the first data among the first memory cells having the threshold voltages that are the second verification voltage so that the number of error bits of the data read from the plurality of first memory cells is reduced.

16. The memory of claim 14, wherein the first verification voltage is set so that a ratio of the number of first memory cells having threshold voltages that are the first verification voltage to the number of first memory cells having adjacent second memory cells that contain the second data among the first memory cells having the threshold voltages that are the first verification voltage so that the number of error bits of the data read from the plurality of first memory cells is reduced, and the second verification voltage is set so that a ratio of the number of first memory cells having threshold voltages that are the second verification voltage to the number of memory cells having the adjacent second memory cells that contain the second data among the first memory cells having the threshold voltages that are the second verification voltage so that the number of error bits of the data read from the plurality of first memory cells is reduced.

17. The memory of claim 11, wherein memory cells corresponding to each other among the plurality of first memory cells and the plurality of memory cells are included in the same cell string.

18. The memory of claim 11, wherein the first data is data in an erase state, and the second data is data in a programmed state.

19. A data decision method comprising:
setting a voltage level of a first verification voltage, and a voltage level of a second verification voltage, wherein the second verification voltage is greater than the first verification voltage;
checking whether threshold voltages of a plurality of memory cells are greater than the first verification voltage;
checking whether the threshold voltages of the plurality of memory cells are greater than the second verification voltage; and
checking threshold voltages of memory cells adjacent to memory cells having threshold voltages greater than the first verification voltage and lower than the second verification voltage among the plurality of memory cells.

20. The data decision method of claim 19, wherein data stored in the memory cells having the threshold voltages greater than the first verification voltage and lower than the second verification voltage among the plurality of memory cells are determined to be data including first data and second data according to data stored in memory cells adjacent thereto.

21. The data decision method of claim 20, wherein data stored in the memory cells having the threshold voltages lower than the first verification voltage among the plurality of memory cells are determined to be first data, and data stored in the memory cells having the threshold voltages greater than the second verification voltage among the plurality of memory cells are determined to be second data.

22. The data decision method of claim 19, wherein the voltage levels of the first and second verification voltages are set to a value inside a system including a memory device or a value inputted from a circuit outside of the system including the memory device.
